(19) United States
(12) Patent Application Publication
(10) Pub. No.: US 2007/0029046 A1
(43) Pub. Date: Feb. 8, 2007

(54) Methods and systems for increasing substrate temperature in plasma reactors

(75) Inventors: Shijian Li, San Jose, CA (US); Siqing Lu, San Jose, CA (US); Irene Chou, San Jose, CA (US); Young S. Lee, San Jose, CA (US); Tetsuya Ishikawa, Saratoga, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/196,850

(22) Filed: Aug. 4, 2005

(51) Int. Cl. C23F 1/00; H01L 21/20; C23C 16/00

(52) U.S. Cl. 156/345.28; 118/723 R; 438/478

(57) ABSTRACT

A substrate processing system is provided. A housing defines a processing chamber. A plasma-generating system is operatively coupled to the processing chamber. A substrate support member is disposed within the processing chamber and configured to hold a substrate during substrate processing. A ceramic insert is disposed over the substrate support member such that the ceramic insert is disposed between the substrate support member and the substrate during substrate processing. A gas-delivery system is configured to introduce gases into the processing chamber. A controller controls the plasma-generating system and the gas-delivery system.

### BACKGROUND OF THE INVENTION

One of the persistent challenges faced in the development of semiconductor technology is the desire to increase the density of circuit elements and interconnections on substrates without introducing spurious interactions between them. Unwanted interactions are typically prevented by providing gaps or trenches that are filled with electrically insulative material to isolate the elements both physically and electrically. As circuit densities increase, however, the widths of these gaps decrease, increasing their aspect ratios and making it progressively more difficult to fill the gaps without leaving voids. The formation of voids when the gap is not filled completely is undesirable because they may adversely affect operation of the completed device, such as by trapping impurities within the insulative material.

Common techniques that are used in such gapfill applications include chemical-vapor deposition (“CVD”) techniques. Conventional thermal CVD processes supply reactive gases to the substrate surface where heat-induced chemical reactions take place to produce a desired film. Plasma-enhanced CVD (“PECVD”) techniques promote excitation and/or dissociation of the reactant gases by the application of radio-frequency (“RF”) energy to a reaction zone near the substrate surface, thereby creating a plasma. The high reactivity of the species in the plasma reduces the energy required for a chemical reaction to take place, and thus lowers the temperature required for such CVD processes when compared with conventional thermal CVD processes. These advantages may be further exploited by high-density-plasma (“HDP”) CVD techniques, in which a dense plasma is formed at low vacuum pressures so that the plasma species are even more reactive. While each of these techniques falls broadly under the umbrella of “CVD techniques,” each of them has characteristic properties that make them more or less suitable for certain specific applications.

It is known that gapfill capabilities are generally improved with an increase in substrate temperature, but there have been a number of challenges associated with efforts to increase substrate temperature. One challenge in particular is that thermal management of a plasma processing system as a whole may present conflicting goals. For example, parts of a plasma processing chamber can be made of materials that may be damaged when exposed to temperatures over a certain threshold. This is particularly true in plasma reactors that include an electrostatic chuck used to hold the substrate in the process chamber and perhaps also in applying an electrical bias to the substrate. When the electrostatic chuck is made with two or more materials, a large temperature change of the chuck, say from 25° C. to 750° C., is likely to damage the chuck because of the difference in thermal expansion coefficient for the different materials. It is also undesirable to have a high-temperature substrate support member because the CVD chamber is periodically cleaned after deposition and a bulk high-temperature substrate support member may not cool sufficiently quickly in the vacuum of the CVD chamber, resulting in the cleaning gas, which usually includes a halogen like fluorine, attacking the high-temperature substrate support member very quickly. Because of its sensitivity to high temperatures, the electrostatic chuck is typically subject to active cooling to maintain its temperature less than about 100° C. This has the effect of reducing the temperature of the substrate in a significant way because of the close proximity of the substrate to the electrostatic chuck during processing.

The desirability of using an increased substrate temperature to improve gapfill characteristics may be dependent on the type of process being performed and on the types of structures that may already have been formed on the substrate. For example, even though they include gaps requiring filling, increases in substrate temperature may be precluded for some premetal dielectric (“PMD”) and intermetal dielectric (“IMD”) processes that typically have relatively low thermal budgets. Other processes, such as many shallow-trench-isolation (“STI”) processes are not constrained by such restrictive thermal budgets and their gapfill capabilities would benefit from increases in substrate temperature.

There is accordingly a remaining need in the art to provide methods and systems for increasing the substrate temperature during plasma processing.

### BRIEF SUMMARY OF THE INVENTION

Embodiments of the invention make use of techniques for increasing the temperature of a substrate, one use of which is to improve gapfill deposition for certain processes, such as STI processes.

In a first set of embodiments, a substrate processing system is provided. A housing defines a processing chamber. A plasma-generating system is operatively coupled to the processing chamber. A substrate support member is disposed within the processing chamber and configured to hold a substrate during substrate processing. A ceramic insert is disposed over the substrate support member such that the ceramic insert is disposed between the substrate support member and the substrate during substrate processing. A gas-delivery system is configured to introduce gases into the processing chamber. A controller controls the plasma-generating system and the gas-delivery system.

Examples of materials that may be used for the ceramic insert comprise AlON, Al₂O₃, AlN, sapphire, and other dielectric ceramic materials that are reasonably resistant to halogen chemistry. The insert may also have features that accommodate certain structural aspects of the processing system. For example, the substrate support member may comprise a plurality of moveable lift pins adapted to move the substrate between a loading position and a processing position. In such instances, the insert may comprise a plurality of lift-pin holes aligned with the moveable lift pins. In other instances, the insert may comprise a plurality of cutouts at a periphery of the insert, with the substrate support member comprising a plurality of protrusions positioned to mate with the cutouts.

In different embodiments, the insert may have a surface area less than a surface area of the substrate, may have a surface area approximately equal to a surface area of the substrate, or may have a surface area greater than a surface area of the substrate. The plasma-generating system may comprise a high-density plasma-generating system. In one embodiment, the substrate support member has a surface having a reflectivity greater than 25% at infrared wavelengths.

In a second set of embodiments, a substrate processing system is also provided. A housing defines a processing chamber. A plasma-generating system is operatively coupled to the processing chamber. A substrate support member is disposed within the processing chamber and is configured to hold a substrate during substrate processing. The substrate support member has a surface having a reflectivity greater than 25% at infrared wavelengths. A gas-delivery system is configured to introduce gases into the substrate processing chamber. A controller controls the plasma-generating system and the gas-delivery system.

In different embodiments, the reflectivity may be greater than 50% at infrared wavelengths or may be greater than 80% at infrared wavelengths. The surface of the substrate support member may be polished. The surface of the substrate support member may also be covered by a substantially transparent coating in some embodiments.

In some instances, a ceramic insert is disposed over the substrate support member such that the ceramic insert is disposed between the substrate support member and the substrate during substrate processing. The insert may comprise a material selected from the group consisting of AlON, Al₂O₃, AlN, and sapphire. In one embodiment, the substrate support member comprises a plurality of moveable lift pins adapted to move the substrate between a loading position and a processing position; in such an embodiment, the insert comprises a plurality of lift-pin holes aligned with the moveable lift pins. The plasma-generating system may comprise a high-density plasma-generating system.

The substrate processing systems of the invention may be used to deposit a film on a substrate. The substrate is loading into the substrate processing chamber. Flows of precursor deposition gases are provided to the substrate processing chamber. A plasma is formed from the flows of the precursor deposition gases. A temperature of the substrate is maintained greater than 750° C.

A further understanding of the nature and advantages of the present invention may be realized by reference to the remaining portions of the specification and the drawings.

### BRIEF DESCRIPTION OF THE DRAWINGS

FIGS. 1A and 1B are schematic cross-sectional drawings illustrating the formation of a void during a gapfill process;

FIG. 2A is a simplified diagram of one embodiment of a high-density-plasma chemical-vapor-deposition system;

FIG. 2B is a simplified cross section of a gas ring that may be used in conjunction with the exemplary processing system of FIG. 2A;

FIGS. 3A-3C are schematic illustrations of structures that may be used for an electrostatic-chuck insert used in some embodiments of the invention;

FIG. 4 is a flow diagram summarizing a gapfill process;

FIG. 5 provides simulation results illustrating a processing-chamber temperature distribution in a system that uses a highly reflective electrostatic-chuck surface;

FIGS. 6A and 6B are graphs providing temperature measurements of wafers processed in chambers according to embodiments of the invention; and

FIG. 7 provides scanning-electron-microscopy views of gapfill structures to provide a comparison of the gapfill capability of different substrate-processing systems.

### DETAILED DESCRIPTION OF THE INVENTION

1. Overview

Traditional methods for heating substrates during semiconductor processing include resistive heating methods in which a substrate is chucked to a support having resistive heating elements, with a flow of heat-conductive gas being provided between the substrate and the support. But the environments used in plasma processing systems, particularly in high-density plasma processing systems, are especially harsh. The pedestal that supports the substrate in such an environment is not only structured to provide RF bias power to the substrate, but should also be resistant to very different environments within the chamber the pedestal is preferably resistant to oxidation when it is exposed to a deposition-gas environment and is preferably resistant to fluorine etching when it is exposed to a cleaning-gas environment. At the same time, the pedestal is preferably capable of accommodating efforts to provide high substrate temperatures that may exceed 800° C. for such processes as STI gapfill processes. Other considerations that affect the design of the pedestal include efforts to ensure its consistent reliability.

In certain existing systems, these conflicting criteria have been addressed by fabricating the pedestal from aluminum and spraying it with a coating of an Al₂O₃ ceramic to a thickness of about 10 mils. During a process requiring a high substrate temperature, the pedestal may be water-cooled to below about 75° C., with the substrate not being chucked to the pedestal and with no gas being flowed between the substrate and pedestal to cool the substrate. With such configurations, the plasma in the processing chamber is typically capable of heating the substrate to a temperature of about 750° C. While this is an acceptably high temperature for many processes, it would be beneficial to have the substrate at an even higher temperature for some processes, such as for STI gapfill processes.

When the inventors were initially confronted with the task of developing ways to increase the substrate temperature, even while maintaining the (close-proximity) pedestal at a relative low temperature, they considered ways in which the thermal communication between the substrate and pedestal could be reduced. By mitigating the effects of this thermal communication, the heating of the substrate that results naturally from its exposure to the plasma would be affected less by efforts to maintain the pedestal temperature. Heat transfer occurs with one of three mechanisms: thermal conduction, thermal convection, and thermal radiation. With the constraints imposed by the structure of plasma processing systems, the inventors identified impairing thermal-radiation and thermal-conduction mechanisms as most likely to be effective in affecting the substrate temperature.

With this recognition, the inventors identified a number of different ways of affecting thermal-transfer mechanisms within different embodiments of the invention using some of them individually or using combinations of them. One technique that uses a thermal radiation mechanism includes increasing the infrared reflectivity of the pedestal so that heat is reflected radiatively away from the pedestal. Such increases in reflectivity may be achieved by polishing a surface of the pedestal, including a highly reflective coating on a surface of the pedestal, anodizing a surface of the pedestal, and the like. In one particular embodiment, a surface of the pedestal is mirror-polished to be highly reflective and the polished surface is coated with a thin and transparent insulator layer that is preferably resistant to oxidation and fluorination. This technique may increase the substrate temperature by about 100° C.

A technique that uses a thermal-conduction mechanism includes using a plurality of distributed contact structures on a top surface of the pedestal. The thickness of the contact structures may be less than about 25 mils, such as being about 10 mils, and are distributed to support the substrate effectively while at the same time providing a minimal area of thermal contact between the substrate and the pedestal. A thickness less than about 25 mils still permits the structure to be self-chucking.

A technique that uses a combination of thermal-radiation and thermal-conduction mechanisms includes providing a ceramic insert between the substrate and the pedestal. The thermal-conductivity characteristics of the insert affect the conduction mechanisms between the substrate and the pedestal; the emissivity properties of the insert may also result in it re-radiating heat absorbed from the substrate. Such re-radiation may be understood from the Stefan-Boltzmann law, in which the energy radiated varies as the fourth power of temperature:
Q∝εA(T₁⁴−T₂⁴).
This expression relates the fact that the radiated energy Q is proportional to the emissivity ε and area A of the body, and is also proportional to the difference in fourth powers of temperature T. In structural arrangements where only the substrate and pedestal are of interest, T₁ may be a temperature of the substrate, T₂ may be a temperature of the pedestal, and ε may be an effective emissivity

$$ɛ = {( \frac{1}{{ɛ}_{1}} + \frac{1}{{ɛ}_{2}} - 1 )}^{- 1}$$

for a substrate having emissivity ε₁ and a substrate support member having emissivity 62. Inclusion of the insert at a temperature Tᵢₙ causes a change in the effective emissivity resulting in a modified energy radiation
Q′∝ε′A(T₁⁴−Tᵢₙ⁴),
for effective emissivity

$${ɛ}^{′} = {( \frac{1}{{ɛ}_{1}} + \frac{1}{{ɛ}_{in}} - 1 )}^{- 1} .$$

Exemplary materials that may be comprised by the ceramic insert include Al₂O₃, AlON, AlN, and sapphire, although other materials may also be used in other embodiments. This technique may increase the substrate temperature by about 40° C.

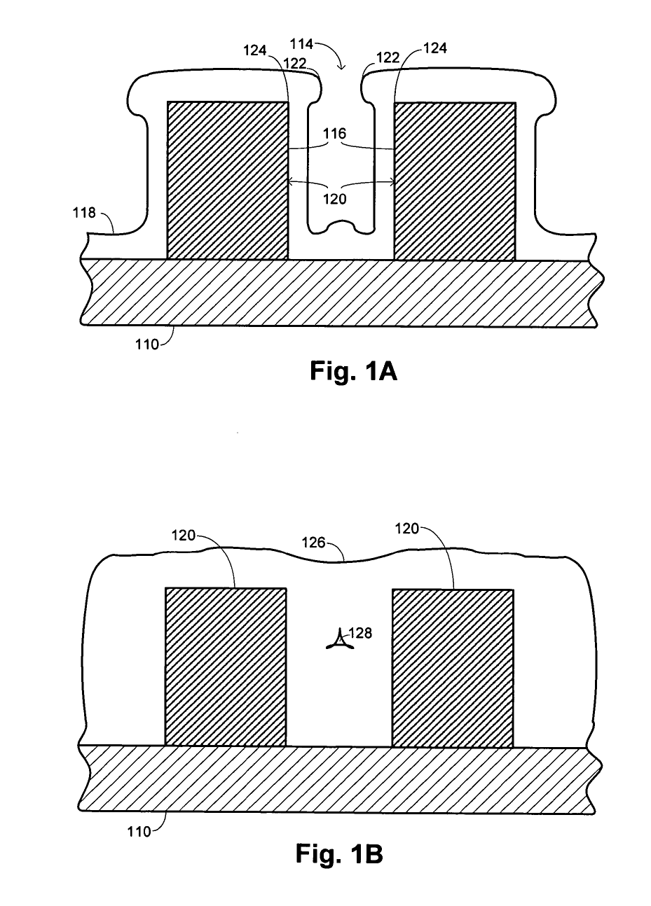

As previously noted, the increase in substrate temperature provided by such mechanisms, when used individually or in combination, may be useful in improving certain types of deposition. One specific type of deposition that benefits from such improvement is gapfill deposition, such as is illustrated with FIGS. 1A and 1B. FIG. 1A shows a vertical cross section of a substrate 110, such as may be provided with a semiconductor wafer, having a layer of features 120. Adjacent features define gaps 114 that are to be filled with dielectric material 118, with the sidewalls 116 of the gaps being defined by the surfaces of the features 120. As the deposition proceeds, dielectric material 118 accumulates on the surfaces of the features 120, as well as on the substrate 110 and forms overhangs 122 at the comers 124 of the features 120. As deposition of the dielectric material 118 continues, the overhangs 122 typically grow faster than at the bottom of the gap 114 in a characteristic breadloafing fashion. Eventually, the overhangs 122 grow together to form the dielectric layer 126 shown in FIG. 1B, preventing deposition into an interior void 128. An increase in substrate temperature as provided by embodiments of the invention permits void-free gapfill for structures having narrower widths and/or large aspect ratios.

2. Exemplary Substrate Processing System

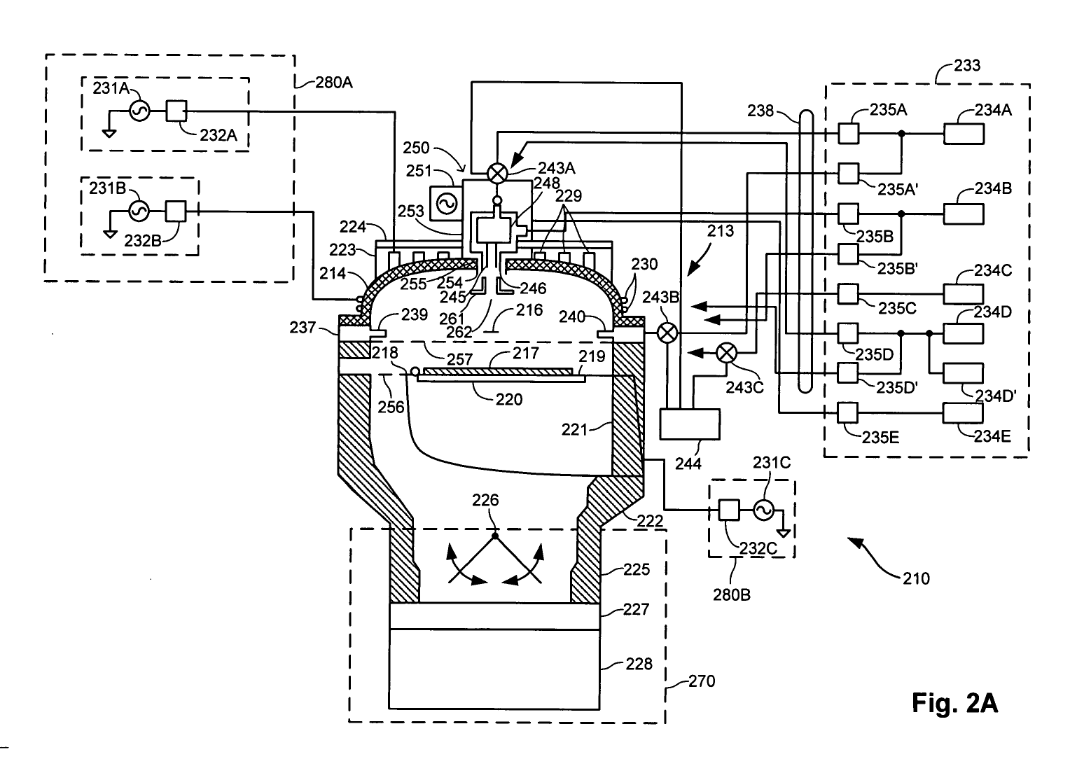

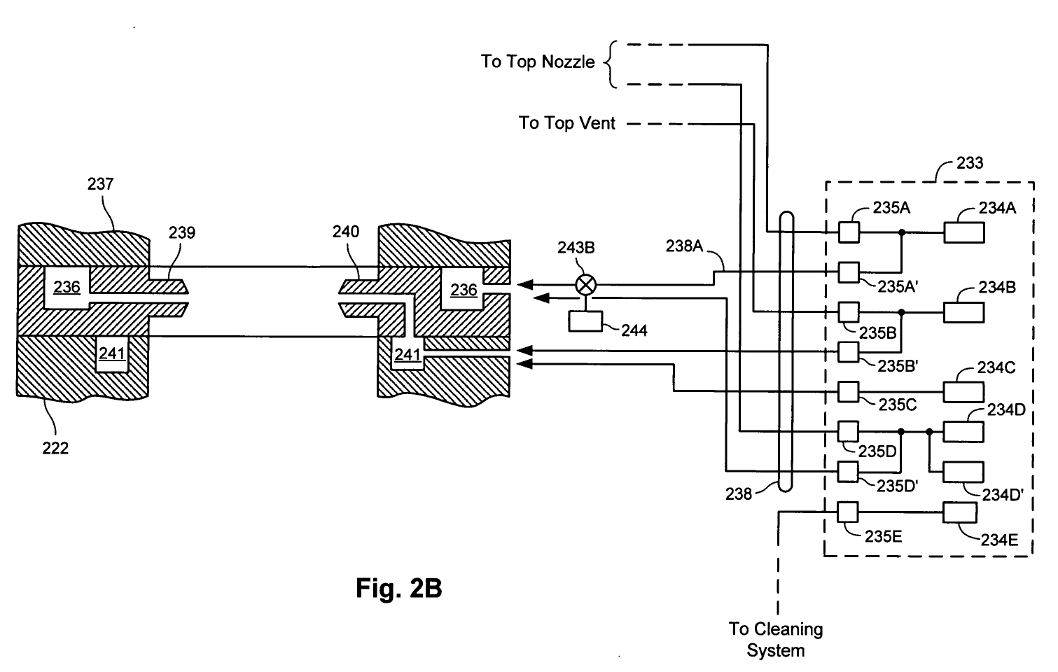

An example of a substrate-processing system within which embodiments of the invention may be implemented is the ULTIMA™ system manufactured by APPLIED MATERIALS, INC., of Santa Clara, Calif., a general description of which is provided in commonly assigned U.S. Pat. No. 6,170,428, “SYMMETRIC TUNABLE INDUCTIVELY COUPLED HDP-CVD REACTOR,” filed Jul. 15, 1996 by Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha, the entire disclosure of which is incorporated herein by reference. An overview of the system is provided in connection with FIGS. 2A and 2B below. FIG. 2A schematically illustrates the structure of such an HDP-CVD system 210 in one embodiment. The system 210 includes a chamber 213, a vacuum system 270, a source plasma system 280A, a bias plasma system 280B, a gas delivery system 233, and a remote plasma cleaning system 250.

The upper portion of chamber 213 includes a dome 214, which is made of a ceramic dielectric material, such as aluminum oxide or aluminum nitride. Dome 214 defines an upper boundary of a plasma processing region 216. Plasma processing region 216 is bounded on the bottom by the upper surface of a substrate 217 and a substrate support member 218.

A heater plate 223 and a cold plate 224 surmount, and are thermally coupled to, dome 214. Heater plate 223 and cold plate 224 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 213 includes a body member 222, which joins the chamber to the vacuum system. A base portion 221 of substrate support member 218 is mounted on, and forms a continuous inner surface with, body member 222. Substrates are transferred into and out of chamber 213 by a robot blade (not shown) through an insertion/removal opening (not shown) in the side of chamber 213. Lift pins (not shown) are raised and then lowered under the control of a motor (also not shown) to move the substrate from the robot blade at an upper loading position 257 to a lower processing position 256 in which the substrate is placed on a substrate receiving portion 219 of substrate support member 218. Substrate receiving portion 219 includes an electrostatic chuck 220 that secures the substrate to substrate support member 218 during substrate processing. In a preferred embodiment, substrate support member 218 is made from an aluminum oxide or aluminum ceramic material. Further details of the substrate support member in embodiments of the invention are provided below.

Vacuum system 270 includes throttle body 225, which houses twin-blade throttle valve 226 and is attached to gate valve 227 and turbo-molecular pump 228. It should be noted that throttle body 225 offers minimum obstruction to gas flow, and allows symmetric pumping. Gate valve 227 can isolate pump 228 from throttle body 225, and can also control chamber pressure by restricting the exhaust flow capacity when throttle valve 226 is fully open. The arrangement of the throttle valve, gate valve, and turbo-molecular pump allow accurate and stable control of chamber pressures up to about 1 millitorr to about 2 torr.

The source plasma system 280A includes a top coil 229 and side coil 230, mounted on dome 214. A symmetrical ground shield (not shown) reduces electrical coupling between the coils. Top coil 229 is powered by top source RF (SRF) generator 231A, whereas side coil 230 is powered by side SRF generator 23 1B, allowing independent power levels and frequencies of operation for each coil. This dual coil system allows control of the radial ion density in chamber 213, thereby improving plasma uniformity. Side coil 230 and top coil 229 are typically inductively driven, which does not require a complimentary electrode. In embodiments of the invention, the side coil is included in a side-coil assembly having the characteristics discussed above. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 280B includes a bias RF (“BRF”) generator 231C and a bias matching network 232C. The bias plasma system 280B capacitively couples substrate portion 217 to body member 222, which act as complimentary electrodes. The bias plasma system 280B serves to enhance the transport of plasma species (e.g., ions) created by the source plasma system 280A to the surface of the substrate.

RF generators 231A and 231B include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 232A and 232B match the output impedance of generators 231A and 231B with their respective coils 229 and 230. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 233 provides gases from several sources, 234A-234E chamber for processing the substrate via gas delivery lines 238 (only some of which are shown). As would be understood by a person of skill in the art, the actual sources used for sources 234A-234E and the actual connection of delivery lines 238 to chamber 213 varies depending on the deposition and cleaning processes executed within chamber 213. Gases are introduced into chamber 213 through a gas ring 237 and/or a top nozzle 245. FIG. 2B is a simplified, partial cross-sectional view of chamber 213 showing additional details of gas ring 237.

In one embodiment, first and second gas sources, 234A and 234B, and first and second gas flow controllers, 235A′ and 235B′, provide gas to ring plenum 236 in gas ring 237 via gas delivery lines 238 (only some of which are shown). Gas ring 237 has a plurality of source gas nozzles 239 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 237 has 12 source gas nozzles made from an aluminum oxide ceramic.

Gas ring 237 also has a plurality of oxidizer gas nozzles 240 (only one of which is shown), which in a preferred embodiment are co-planar with and shorter than source gas nozzles 239, and in one embodiment receive gas from body plenum 241. In some embodiments it is desirable not to mix source gases and oxidizer gases before injecting the gases into chamber 213. In other embodiments, oxidizer gas and source gas may be mixed prior to injecting the gases into chamber 213 by providing apertures (not shown) between body plenum 241 and gas ring plenum 236. In one embodiment, third, fourth, and fifth gas sources, 234C, 234D, and 234D′, and third and fourth gas flow controllers, 235C and 235D′, provide gas to body plenum via gas delivery lines 238. Additional valves, such as 243B (other valves not shown), may shut off gas from the flow controllers to the chamber. In implementing certain embodiments of the invention, source 234A comprises a silane SiH₄ source, source 234B comprises a molecular oxygen O₂ source, source 234C comprises a silane SiH₄ source, source 234D comprises a helium He source, and source 234D′ comprises a molecular hydrogen H₂ source.

In embodiments where flammable, toxic, or corrosive gases are used, it may be desirable to eliminate gas remaining in the gas delivery lines after a deposition. This may be accomplished using a 3-way valve, such as valve 243B, to isolate chamber 213 from delivery line 238A and to vent delivery line 238A to vacuum foreline 244, for example. As shown in FIG. 2A, other similar valves, such as 243A and 243C, may be incorporated on other gas delivery lines. Such three-way valves may be placed as close to chamber 213 as practical, to minimize the volume of the unvented gas delivery line (between the three-way valve and the chamber). Additionally, two-way (on-off) valves (not shown) may be placed between a mass flow controller (“MFC”) and the chamber or between a gas source and an MFC.

Referring again to FIG. 2A, chamber 213 also has top nozzle 245 and top vent 246. Top nozzle 245 and top vent 246 allow independent control of top and side flows of the gases, which improves film uniformity and allows fine adjustment of the film's deposition and doping parameters. Top vent 246 is an annular opening around top nozzle 245. In one embodiment, first gas source 234A supplies source gas nozzles 239 and top nozzle 245. Source nozzle MFC 235A′ controls the amount of gas delivered to source gas nozzles 239 and top nozzle MFC 235A controls the amount of gas delivered to top gas nozzle 245. Similarly, two MFCs 235B and 235B′ may be used to control the flow of oxygen to both top vent 246 and oxidizer gas nozzles 240 from a single source of oxygen, such as source 234B. In some embodiments, oxygen is not supplied to the chamber from any side nozzles. The gases supplied to top nozzle 245 and top vent 246 may be kept separate prior to flowing the gases into chamber 213, or the gases may be mixed in top plenum 248 before they flow into chamber 213. Separate sources of the same gas may be used to supply various portions of the chamber.

A remote microwave-generated plasma cleaning system 250 is provided to periodically clean deposition residues from chamber components. The cleaning system includes a remote microwave generator 251 that creates a plasma from a cleaning gas source 234E (e.g., molecular fluorine, nitrogen trifluoride, other fluorocarbons or equivalents) in reactor cavity 253. The reactive species resulting from this plasma are conveyed to chamber 213 through cleaning gas feed port 254 via applicator tube 255. The materials used to contain the cleaning plasma (e.g., cavity 253 and applicator tube 255) must be resistant to attack by the plasma. The distance between reactor cavity 253 and feed port 254 should be kept as short as practical, since the concentration of desirable plasma species may decline with distance from reactor cavity 253. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 220, do not need to be covered with a dummy wafer or otherwise protected, as may be required with an in situ plasma cleaning process. In FIG. 2A, the plasma-cleaning system 250 is shown disposed above the chamber 213, although other positions may alternatively be used.

A baffle 261 may be provided proximate the top nozzle to direct flows of source gases supplied through the top nozzle into the chamber and to direct flows of remotely generated plasma. Source gases provided through top nozzle 245 are directed through a central passage 262 into the chamber, while remotely generated plasma species provided through the cleaning gas feed port 254 are directed to the sides of the chamber 213 by the baffle 261.

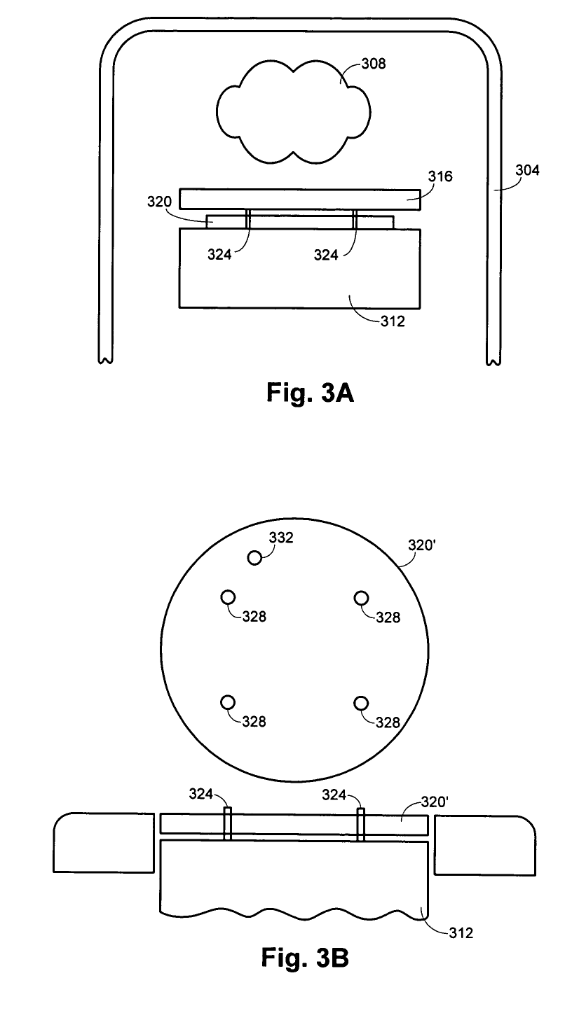

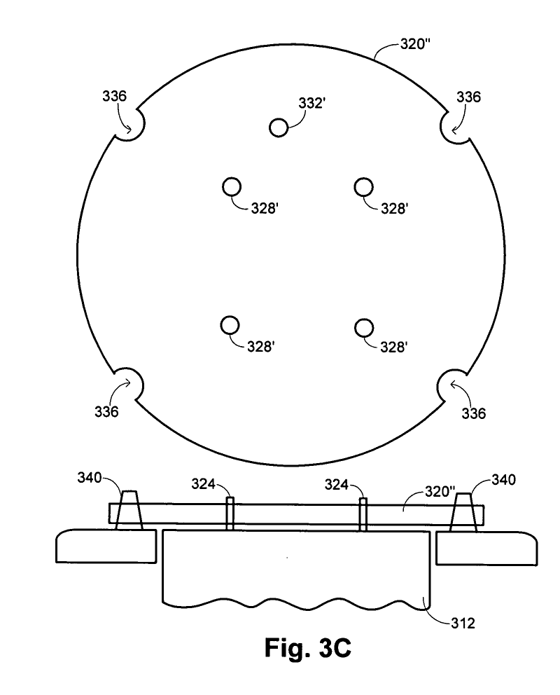

FIGS. 3A-3C are schematic drawings that illustrate certain details of the substrate support member in embodiments that provide a ceramic insert between the substrate support member and the substrate. FIG. 3A provides a side view of a portion of the processing chamber defined by the chamber walls 304, with a plasma 308 formed within the chamber over a substrate 316. The substrate 316 is supported by lift pins 324 that protrude through the ceramic insert 320, which is disposed between the substrate 316 and the substrate support member 312.

This general configuration may be realized in a number of different specific ways, examples of which are illustrated with FIGS. 3B and 3C. Both of these figures include top portions that show a top view of the ceramic insert and bottom portions that show a side-view detail of the insert's integration with the substrate support member. FIG. 3B shows an example where the insert 320′ has a diameter that is less than a diameter of the substrate 316. The insert 320′ includes a plurality of lift-pin holes 328 through which the lift pins 324 may protrude to support the substrate 316 and to move the substrate 316 between an upper loading position and a lower processing position. In addition, the insert 320′ may comprise a WTM hole 332.

In an alternative embodiment illustrated in FIG. 3C, the insert 320″ comprises a plurality of cutouts 336 disposed at a periphery of the insert 320″. Such cutouts 336 may conveniently mate with protrusions 340 comprised by the substrate support member, thereby providing a convenient mechanism for positioning the insert 320″ and simplifying lining up the lift pins 324 with the corresponding lift-pin holes 328′. While the cutouts 336 are shown in the drawing as having approximately semicircular cross sections, other cutout shapes may be used in different embodiments, usually with the cutout shapes matching shapes of the protrusions 340. The insert 320″ shown in FIG. 3C also has a larger diameter than the insert 320′ illustrated in FIG. 3B, a feature that may provide more protection to the pedestal, particularly when the pedestal is polished to provide a high infrared reflectivity. The larger insert diameter may also increase substrate-edge lateral heating. In some embodiments, the insert 320″ may have a diameter approximately equal to the diameter of the substrate 316, and in other embodiments it may even have a diameter that exceeds the diameter of the substrate 316.

To reduce heat transfer to the substrate support member 312, a surface of the substrate member may be provided with a high reflectivity at infrared wavelengths, which are typically in the range of about 1-1000 μm. The reflectivity of the surface at these wavelengths may be greater than 25% in some embodiments, meaning that the intensity of infrared radiation reflected from the surface is greater than 50% of the intensity of infrared radiation incident on the surface. In other embodiments, the reflectivity of the surface may be greater than 80% or may even be greater than 90% or 95% in some instances. Such high reflectivities may be achieved by polishing, anodization, providing coatings, and/or combinations of such techniques. A thin, transparent insulator coating may also advantageously protect the highly reflective surface from aging and or damaging effects of noise.

3. Gap Fill Processes

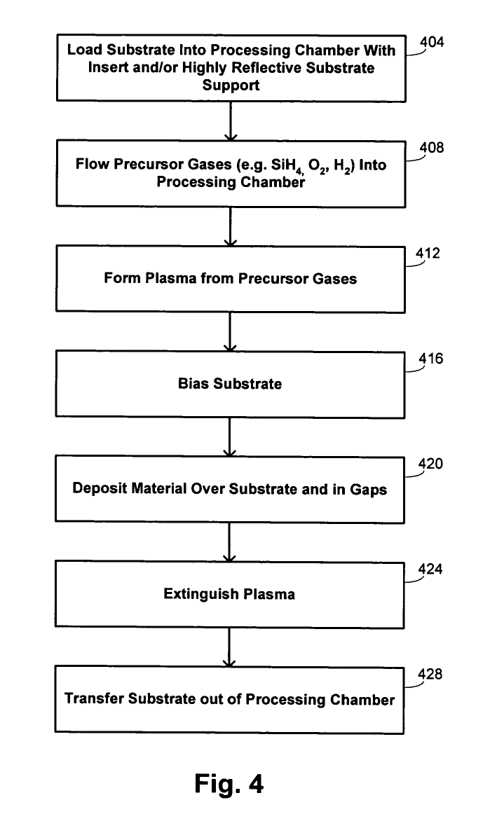

For purposes of illustration, FIG. 4 provides a flow diagram of a process that may be used to fill a gap in a substrate having such a gap between adjacent raised features. The process begins with the substrate being loaded into a processing chamber having one or more of the features discussed above, as indicated at block 408. For example, the processing chamber may comprise a substrate support member having a highly reflective surface and/or having a ceramic insert disposed between the substrate support member and the loaded substrate.

Gapfill deposition is initiated by flowing precursor gases to the processing chamber at block 408. For deposition of a silicon oxide layer, such precursor gases may include a silicon-containing gas such as SiH₄ and an oxygen-containing gas such as O₂. In addition, the precursor gases may comprise a fluent gas, which may also act as a sputtering agent. For example, the fluent gas may be provided with a flow of H₂ or with a flow of an inert gas, including a flow of He or even a flow of a heavier inert gas such as Ne, Ar, or Xe. The level of sputtering provided by the different fluent gases is inversely related to their atomic mass (or molecular mass in the case of H₂), with H₂ producing even less sputtering than He. Flows may sometimes be provided of multiple gases, such as by providing both a flow of H₂ and a flow of He, which mix in the processing chamber. Alternatively, multiple gases may sometimes be used to provide the fluent gas, such as when a flow of H₂/He is provided in to the process chamber. It is also possible to provide separate flows of higher-mass gases, or to include higher-mass gases in the premixture.

In some instances, it may be desirable for the deposited film to be doped. The inclusion of dopants may be used to alter certain physical properties of the film, such as its dielectric constant, index of refraction, stress, and the like. Dopants may be added to the film by including a precursor gas with the desired dopant, such as by including a flow of SiF₄ to fluorinate the film, including a flow of PH₃ to phosphorate the film, including a flow of B₂H₆ to boronate the film, including a flow of N₂ to nitrogenate the film, and the like.

As indicated at block 412, a plasma is formed from the precursor gases. In some embodiments, the plasma may be a high-density plasma having an ion density that exceeds 10¹¹ ions/cm². Also, in some instances the deposition characteristics may be affected by applying an electrical bias to the substrate. Application of such a bias causes the ionic species of the plasma to be attracted to the substrate, sometimes resulting in increased sputtering. The environment within the processing chamber may also be regulated in other ways in some embodiments, such as by controlling the pressure within the processing chamber, controlling the flow rates of the precursor gases and where they enter the processing chamber, controlling the power used in generating the plasma, controlling the power used in biasing the substrate, and the like. Under the conditions defined for processing a particular substrate, material is thus deposited over the substrate and within the gaps as indicated at block 420.

After deposition is completed, the plasma is extinguished at block 424 and the substrate transferred out of the processing chamber at block 428. In some instances, prior to the gapfill process, an initial lining layer may be deposited over the substrate as an in situ steam generation (“ISSG”) or other thermal oxide layer, or perhaps a silicon nitride layer. One benefit to depositing such a liner prior to filling the gaps in the substrate is to provide appropriate corner rounding, which may aid in avoiding such effects as early gate breakdown in transistors that are formed. In addition, such a liner may aid in relieving stress after the gapfill deposition.

4. Results

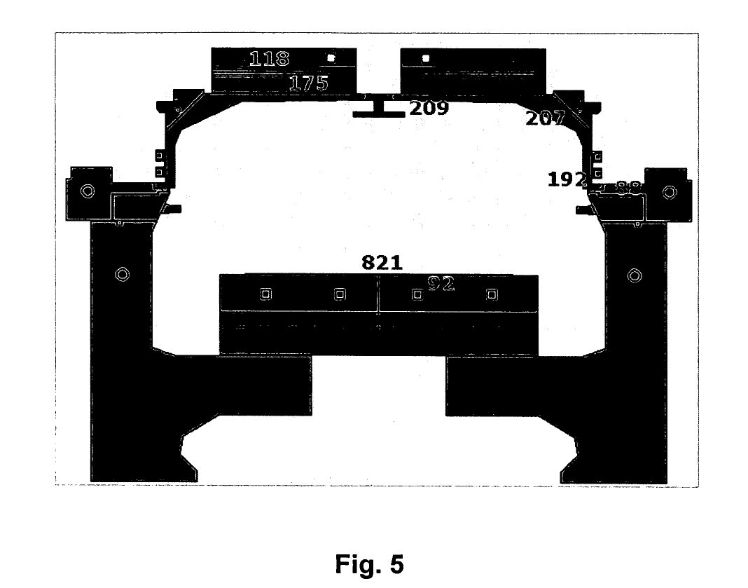

The inventors have performed a number of tests to verify that the structures described herein have the desired effect of increasing the substrate temperature. The results of such tests, which include both simulations and experimental tests, are described below in connection with FIGS. 5-7.

The results of a full-scale thermal simulation on a substrate processing chamber that includes a highly reflective substrate support structure. The simulation was performed with a model of a substrate processing chamber having the structure illustrated in FIG. 5. The results of the simulation are presented graphically and with numerical values showing the temperature at different points in the processing chamber in ° C. Results of the simulation confirm that effective thermal control may be maintained throughout the chamber as a whole even while achieving an increase in the substrate temperature. As evident from the drawing, a substrate temperature of about 821° C. may be achieved, a value that is about 80° C. higher than is achieved with a conventional substrate processing system. In addition, this high substrate temperature is achieved even while maintaining an acceptable temperature of the substrate support member <100° C.

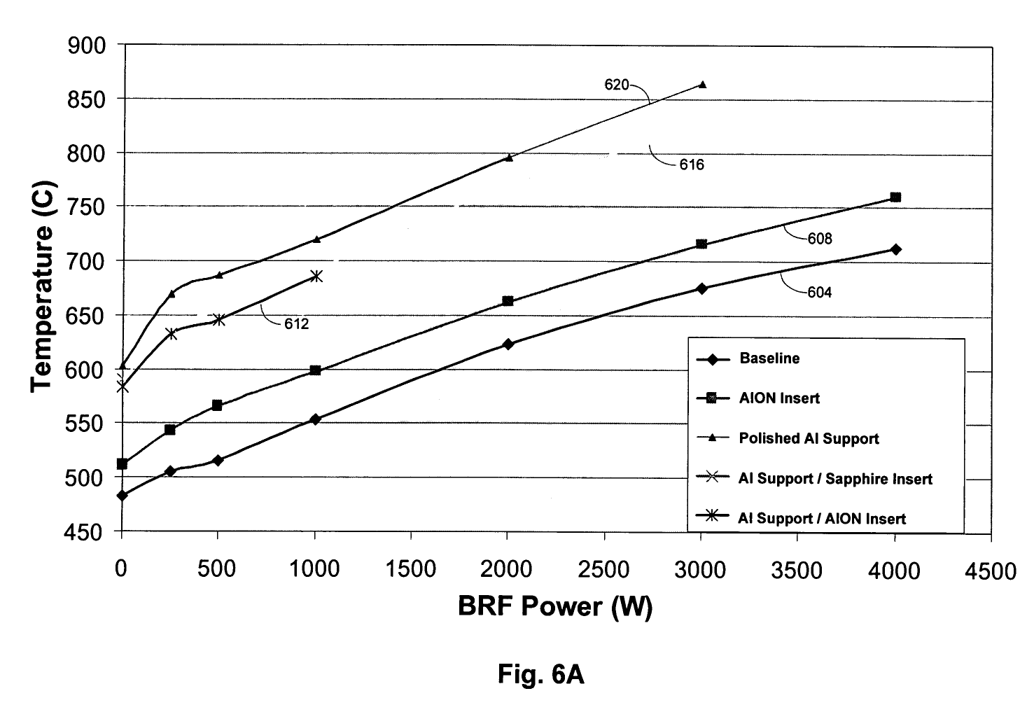

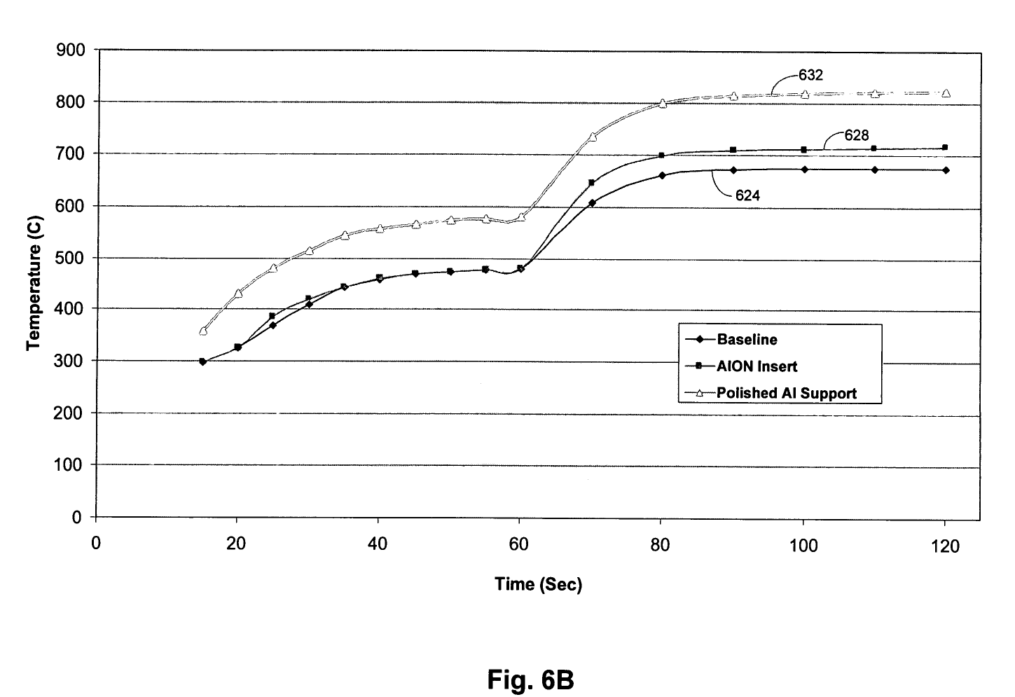

Experimental results testing the effect of both the highly reflective substrate support structure and of including a ceramic insert between the support and the substrate are presented in FIGS. 6A and 6B. The results provided in FIG. 6A show the dependence on bias RF power applied to the substrate, measured in a deposition process performed on a 200-mm-diameter silicon substrate with a plasma formed from flows of He and O₂ to the substrate processing chamber. The plasma was formed by application of top and side RF source powers of 4800 W each. The measurements of substrate temperature were made after one minute of application of the top/side RF source powers and then after another minute of application of both the top/side RF source powers and the bias RF power.

In FIG. 6A, the baseline results for a conventional substrate processing chamber are provided by curve 604. This curve shows the general trend that is shared by all the results that greater substrate temperatures result from application of higher bias powers. The effect of including an insert is shown with curve 608, which provides results when an AlON insert is disposed between the substrate and the substrate support member. Curve 620 shows measured substrate temperatures when the substrate support comprises a bare polished Al support, and curves 612 and 616 respectively provide measured substrate temperatures for a AlON and sapphire insert disposed between the substrate and an Al substrate support member. The experimental measurements demonstrate that an increase in substrate temperature of about 40-50° C. is achieved by inclusion of an insert and an increase in substrate temperature of about 150° C. is achieved by having a surface of the substrate support member be highly reflective.

The results provided in FIG. 6B show the time dependence for similar tests on a 200-mm-diameter silicon substrate exposed to a He-O₂ plasma. The plasma was generated by application of top and side source RF powers of 4800 W each. The substrate was exposed to such a plasma for one minute, after which a bias RF power of 3000 W was applied for an additional minute. The baseline results for a conventional substrate processing chamber are provided by curve 624. These results show that the temperature of the substrate increases from exposure to the plasma, and increases further upon application of the bias power at the 60-second mark, reaching an asymptotic value at around 80-90 seconds. This general behavior is evident also in curves 628 and 632, which respectively show results of measurements when an AlON insert is disposed between the substrate and the substrate support member and when the substrate support member has a highly reflective polished Al surface. The effect of each of these techniques is similar to the effect seen from the results of FIG. 6A. In particular, the inclusion of an insert results in a temperature increase of the substrate by about 40-50° C. and the use of a substrate support member having a highly reflective surface results in a temperature increase of the substrate by about 150° C.

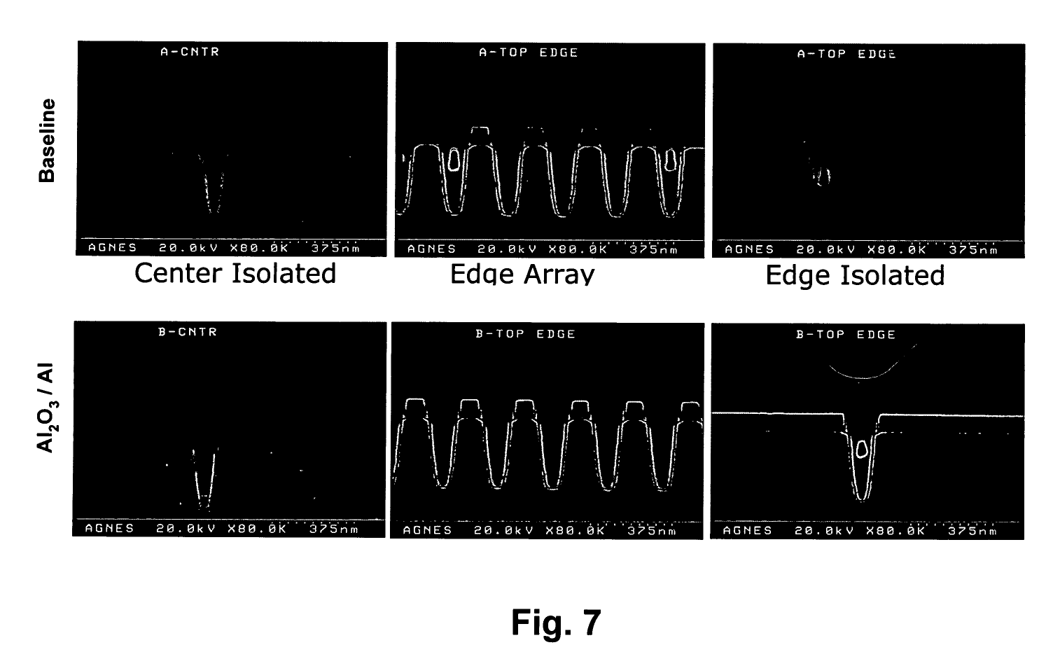

The experimental tests performed by the inventors have also confirmed that improved gapfill results from use of the techniques described herein for increasing substrate temperature. This is illustrated in FIG. 7, which shows scanning-electron-microscopy (“SEM”) views of gap structures. The top three panels of the drawing result from the use of an HDP gapfill process using a conventional processing chamber, while the bottom three panels show corresponding results with substrate processing chamber having an Al₂O₃ insert disposed between the substrate and a polished Al substrate support member. The temperature difference for results collected for the top and bottom panels was about 90° C. The left panels are SEM views of an isolated gap at the center of a silicon substrate; the center panels are SEM views of an array of gaps at the edge of a silicon substrate; and the right panels are SEM views of an isolated gap at the edge of a silicon substrate.

The results clearly show improved gapfill in the lower panels. Such improvement is perhaps most clear in the center panels where large voids that were formed with the conventional structure are completely absent with the modified structure, but are also evident in the left and right panels where smaller voids are eliminated and/or larger voids are reduced in size. The results presented in FIG. 7 are intended merely to illustrate the effect of the techniques described herein for increasing substrate temperature by providing a relative comparison. The inventors anticipate from these results that a wide variety of narrow-width high-aspect ratios may be effectively filled with processes optimized for the characteristics of specific structures using the techniques described herein.

Those of ordinary skill in the art will realize that specific parameters can vary for different processing chambers and different processing conditions, without departing from the spirit of the invention. Other variations will also be apparent to persons of skill in the art. These equivalents and alternatives are intended to be included within the scope of the present invention. Therefore, the scope of this invention should not be limited to the embodiments described, but should instead be defined by the following claims.

What is claimed is:

1. A substrate processing system comprising:
a housing defining a processing chamber;
a plasma-generating system operatively coupled to the processing chamber;
a substrate support member disposed within the processing chamber and configured to hold a substrate during substrate processing;
a ceramic insert disposed over the substrate support member such that the ceramic insert is disposed between the substrate support member and the substrate during substrate processing;
a gas-delivery system configured to introduce gases into the processing chamber; and
a controller for controlling the plasma-generating system and the gas-delivery system.

2. The substrate processing system recited in claim 1 wherein the ceramic insert comprises AlON.

3. The substrate processing system recited in claim 1 wherein the ceramic insert comprises Al₂O₃.

4. The substrate processing system recited in claim 1 wherein the ceramic insert comprise AlN.

5. The substrate processing system recited in claim 1 wherein the ceramic insert comprises sapphire.

6. The substrate processing system recited in claim 1 wherein:
the substrate support member comprises a plurality of moveable lift pins adapted to move the substrate between a loading position and a processing position; and
the insert comprises a plurality of lift-pin holes aligned with the moveable lift pins.

7. The substrate processing system recited in claim 1 wherein:
the insert comprises a plurality of cutouts at a periphery of the insert; and
the substrate support member comprises a plurality of protrusions positioned to mate with the cutouts.

8. The substrate processing system recited in claim 1 wherein the insert has a surface area less than a surface area of the substrate.

9. The substrate processing system recited in claim 1 wherein the insert has a surface area approximately equal to a surface area of the substrate.

10. The substrate processing system recited in claim 1 wherein the insert has a surface area greater than a surface area of the substrate.

11. The substrate processing system recited in claim 1 wherein the plasma-generating system comprises a high-density plasma-generating system.

12. The substrate processing system recited in claim 1 wherein the substrate support member has a surface having a reflectivity greater than 80% at infrared wavelengths.

13. A substrate processing system comprising:
a housing defining a processing chamber;
a plasma-generating system operatively coupled to the processing chamber;
a substrate support member disposed within the processing chamber and configured to hold a substrate during substrate processing, wherein the substrate support member has a surface having a reflectivity greater than 25% at infrared wavelengths;
a gas-delivery system configured to introduce gases into the substrate processing chamber; and
a controller for controlling the plasma-generating system and the gas-delivery system.

14. The substrate processing system recited in claim 13 wherein the reflectivity is greater than 50% at infrared wavelengths.

15. The substrate processing system recited in claim 13 wherein the reflectivity is greater than 80% at infrared wavelengths.

16. The substrate processing system recited in claim 13 wherein the surface of the substrate support member is polished.

17. The substrate processing system recited in claim 13 wherein the surface of the substrate support member is covered by a substantially transparent coating.

18. The substrate processing system recited in claim 13 further comprising a ceramic insert disposed over the substrate support member such that the ceramic insert is disposed between the substrate support member and the substrate during substrate processing.

19. The substrate processing system recited in claim 18 wherein the insert comprises a material selected from the group consisting of AlON, Al₂O₃, AlN, and sapphire.

20. The substrate processing system recited in claim 18 wherein:
the substrate support member comprises a plurality of moveable lift pins adapted to move the substrate between a loading position and a processing position; and
the insert comprises a plurality of lift-pin holes aligned with the moveable lift pins.

21. The substrate processing system recited in claim 13 wherein the plasma-generating system is a high-density plasma-generating system.

22. A method for depositing a film on a substrate, the method comprising:
loading the substrate into a substrate processing chamber that houses a substrate support member and a ceramic insert disposed over the substrate support member such that the ceramic insert is disposed between the substrate support member and the substrate after loading;
providing flows of precursor deposition gases to the substrate processing chamber;
forming a plasma from the flows of the precursor deposition gases; and
maintaining a temperature of the substrate greater than 750° C.

23. The method recited in claim 22 wherein the ceramic insert is selected from the group consisting of AlON, Al₂O₃, AlN, and sapphire.

24. The method recited in claim 22 wherein forming the plasma comprises forming a high-density plasma.

25. The method recited in claim 24 wherein the substrate has a shallow-trench-isolation gap formed between adjacent raised surfaces, the method further comprising depositing the film over the substrate and within the gap using a process that has simultaneous deposition and sputtering components.

26. The method recited in claim 22 wherein the substrate support member has a surface having a reflectivity greater than 25% at infrared wavelengths.

27. A method for depositing a film on a substrate, the method comprising:
loading the substrate into a substrate processing chamber that houses a substrate support member having a substrate that has a reflectivity greater than 25% at infrared wavelengths;
providing flows of precursor deposition gases to the substrate processing chamber;
forming a plasma from the flows of the precursor deposition gases; and
maintaining a temperature of the substrate greater than 750° C.

28. The method recited in claim 27 wherein the reflectivity is greater than 50% at infrared wavelengths.

29. The method recited in claim 27 wherein the reflectivity is greater than 80% at infrared wavelengths.

30. The method recited in claim 27 wherein the surface of the substrate support member is covered by a substantially transparent coating.

31. The method recited in claim 27 wherein forming the plasma comprises forming a high-density plasma.

32. The method recited in claim 31 wherein the substrate has a shallow-trench-isolation gap formed between adjacent raised surfaces, the method further comprising depositing the film over the substrate and within the gap using a process that has simultaneous deposition and sputtering components.

33. The method recited in claim 27 wherein the substrate processing chamber further houses a ceramic insert disposed over the substrate support member such that the ceramic insert is disposed between the substrate support member and the substrate after loading.
